(19) United States
(12) Patent Application Publication
(10) Pub. No.: US 2011/0189846 A1
(43) Pub. Date: Aug. 4, 2011

(54) METHODS OF MANUFACTURING NON-VOLATILE MEMORY DEVICES

(76) Inventors: Jeong Gil Lee, Goyang-si (KR); Chang-Won Lee, Seongnam-si (KR); Sang-Woo Lee, Seoul (KR); Sun-Woo Lee, Namdong-gu (KR); Ki-Hyun Hwang, Seongnam-si (KR); Jae-Hwa Park, Yongin-si (KR); Eun-Ji Jung, Hwaseong-si (KR)

(21) Appl. No.: 13/020,979

(22) Filed: Feb. 4, 2011

(30) Foreign Application Priority Data
Feb. 4, 2010 (KR) 10-2010-0010212

(51) Int. Cl. H01L 21/28

(52) U.S. Cl. 438/591; 438/594; 257/E21.21; 257/E21.209

(57) ABSTRACT

A method of manufacturing a non-volatile memory device including a tunnel oxide layer, a preliminary charge storing layer and a dielectric layer on a semiconductor layer is disclosed. A first polysilicon layer is formed on the dielectric layer. A barrier layer and a second polysilicon layer are formed on the first polysilicon layer. The second polysilicon layer, the barrier layer, the first polysilicon layer, the dielectric layer, the preliminary charge storing layer and the tunnel oxide layer are patterned to form a tunnel layer pattern, a charge storing layer pattern, a dielectric layer pattern, a first control gate pattern, a barrier layer pattern and a second polysilicon pattern. A nickel layer is formed on the second polysilicon layer. Heat treatment is performed with respect to the second polysilicon pattern and the nickel layer to form a second control gate pattern including NiSi on the barrier layer pattern.

### CROSS REFERENCE TO RELATED APPLICATION AND CLAIM OF PRIORITY

This application claims priority under 35 USC §119 to Korean Patent Application No. 10-2010-0010212, filed on Feb. 4, 2010 in the Korean Intellectual Property Office (KIPO), the disclosure of which is incorporated herein by reference in its entirety.

### BACKGROUND

1. Field

The inventive concept relates to non-volatile memory devices and methods of manufacturing the same. More particularly, the inventive concept relates to non-volatile flash memory devices and methods of manufacturing the same.

2. Description of the Related Art

As semiconductor devices become more highly integrated, the line width of a gate electrode has been decreased, and impurity doped regions, e.g., source/drain regions in flash memory devices, have also gradually decreased. When the line width of the gate electrode decreases, the resistance of the gate electrode may increase, which may degrade the electric characteristics of the flash memory device. Accordingly, gate electrodes have typically been formed using a material having a low resistance and that can be easily patterned without generating process defects.

However, application of a conductive material having high thermal stability, low resistance and good surface morphology without generating cohesion problems, and formation of gate electrodes having small line widths by using the conductive material, have been difficult tasks.

### SUMMARY

Some embodiments provide non-volatile memory devices including a gate having a low resistance.

Some embodiments provide methods of manufacturing a non-volatile memory device including a gate having a low resistance.

According to some embodiments, a non-volatile memory device is provided. The device includes a tunnel layer pattern, a charge storing layer pattern and a dielectric layer pattern integrated on a substrate. On the dielectric layer pattern, a first control gate pattern including silicon is formed. The first control gate pattern may include polysilicon in some embodiments. A barrier layer pattern is provided on the first control gate pattern and a second control gate pattern including NiSi is formed on the barrier layer pattern. The barrier layer pattern may be configured to block the migration of silicon into the second control gate pattern during subsequent high temperature processing, which may otherwise undesirably change the phase of the second control gate pattern, for example, to NiSi₂.

In some embodiments, the barrier layer pattern may include tungsten (W), titanium (Ti), tantalum (Ta), cobalt titanium (CoTi), nickel platinum (NiPt), titanium nitride (TiN), tantalum nitride (TaN), cobalt silicide (CoSi₂), tungsten silicide (WSiₓ), molybdenum silicide (MoSiₓ), platinum silicide (PtSiₓ), titanium silicide (TiSiₓ) and/or nickel cobalt silicide (NiCoSiₓ). The compounds may be used alone or in combination thereof. In the chemical formula, x may represent a real number.

In some embodiments, the barrier layer pattern may include tungsten silicide (WSiₓ).

In some embodiments, the barrier layer pattern may have a thickness of about 50 angstroms to about 150 angstroms.

In some embodiments, a line width of the second control gate pattern may be about 90% to about 110% of a line width of an underlying first control gate pattern.

According to some embodiments, there is provided a method of manufacturing a non-volatile memory device. In the method, a tunnel oxide layer, a preliminary charge storing layer and a dielectric layer are formed on a substrate. A first polysilicon layer is formed on the dielectric layer. A barrier layer for preventing a phase change and a second polysilicon layer are formed on the first polysilicon layer. Then, the second polysilicon layer, the barrier layer, the first polysilicon layer, the dielectric layer, the preliminary charge storing layer and the tunnel oxide layer are patterned to form a tunnel layer pattern, a charge storing layer pattern, a dielectric layer pattern, a first control gate pattern, a barrier layer pattern and a second polysilicon pattern. A nickel layer is formed on the second polysilicon layer. A heat treatment is performed with respect to the second polysilicon pattern and the nickel layer to form a second control gate pattern including NiSi on the barrier layer.

In some embodiments, the barrier layer may include tungsten (W), titanium (Ti), tantalum (Ta), cobalt titanium (CoTi), nickel platinum (NiPt), titanium nitride (TiN), tantalum nitride (TaN), cobalt silicide (CoSi₂), tungsten silicide (WSiₓ), molybdenum silicide (MoSiₓ), platinum silicide (PtSiₓ), titanium silicide (TiSiₓ) and/or nickel cobalt silicide (NiCoSiₓ). The compounds may be used alone or in combination thereof. In the chemical formula, x may represent a real number.

In some embodiments, the barrier layer may be formed using tungsten silicide (WSiₓ).

In some embodiments, the barrier layer may be formed to a thickness of about 50 angstoms to about 150 angstoms.

In some embodiments, the second control gate pattern may be formed at a temperature range of about 320° C. to about 750° C.

In some embodiments, the second control gate pattern may be formed by performing a first heat treatment of the second polysilicon pattern and the nickel layer at a temperature range of about 320° C. to about 350° C. Then, a second heat treatment of the second polysilicon pattern and the nickel layer may be performed at a temperature range of about 400° C. to about 650° C.

In some embodiments, a blocking layer may be further formed at sidewall portions of the tunnel layer pattern, the charge storing layer pattern, the dielectric layer pattern, the first control gate pattern, the barrier layer pattern and the second polysilicon pattern.

In some embodiments, the charge storing layer pattern may include polysilicon provided as a floating gate pattern.

In some embodiments, the charge storing layer pattern may include silicon nitride or metal oxide, provided as a charge trapping layer pattern.

In some embodiments, a capping layer may be further formed on the nickel layer.

In some embodiments, a remaining nickel layer may be removed after forming the second control gate pattern.

In some embodiments, a process at a temperature of about 650° C. or higher may be further performed after forming the second control gate pattern.

As explained above, according to some embodiments, a non-volatile memory device may include a second control gate electrode including NiSi and a barrier layer pattern provided under the second control gate electrode. Because of the provision of the barrier layer pattern, a phase change of the second control gate electrode may be reduced or avoided when performing subsequent processes at a temperature of about 700° C. or higher for manufacturing the non-volatile memory device. Since a gate structure included in the non-volatile memory device has an improved thermal stability, a low resistance and a good vertical profile, a non-volatile memory device having an improved performance may be obtained.

### BRIEF DESCRIPTION OF THE DRAWINGS

Example embodiments will be more clearly understood from the following detailed description taken in conjunction with the accompanying drawings. FIGS. 1 to 28 represent example embodiments as described herein.

FIGS. 1A and 1B are cross-sectional views of a non-volatile memory device in accordance with a first example embodiment.

FIGS. 2 to 9 are cross-sectional views for explaining a method of manufacturing a non-volatile memory device in accordance with the first example embodiment.

FIGS. 10 to 12 are cross-sectional views for explaining another method of manufacturing a non-volatile memory device illustrated in FIG. 1.

FIG. 13 is a cross-sectional view of a non-volatile memory device in accordance with a second example embodiment.

FIGS. 14 to 17 are cross-sectional views for explaining a method of manufacturing a non-volatile memory device in accordance with the second example embodiment.

FIG. 18 is a cross-sectional view of a non-volatile memory device in accordance with a third example embodiment.

FIGS. 19 to 22 are cross-sectional views for explaining a method of manufacturing a non-volatile memory device in accordance with the third example embodiment.

FIG. 23 illustrates a graph representing sheet resistances with respect to heat treating temperatures for Samples 1 to 3 and Comparative Sample 1.

FIG. 24 illustrates a graph representing sheet resistances with respect to heat treating temperatures for Samples 4 and 5 and Comparative Sample 2.

FIG. 25 is a block diagram illustrating an electronic device including a non-volatile memory device in accordance with some embodiments.

FIG. 26 is a block diagram illustrating another electronic device including a non-volatile memory device in accordance with some embodiments.

FIG. 27 is a block diagram illustrating further another electronic device including a non-volatile memory device in accordance with some embodiments.

FIG. 28 is a block diagram illustrating still further another electronic device including a non-volatile memory device in accordance with some embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

Hereinafter, example embodiments of non-volatile memory devices will be explained in detail.

### Example Embodiment 1

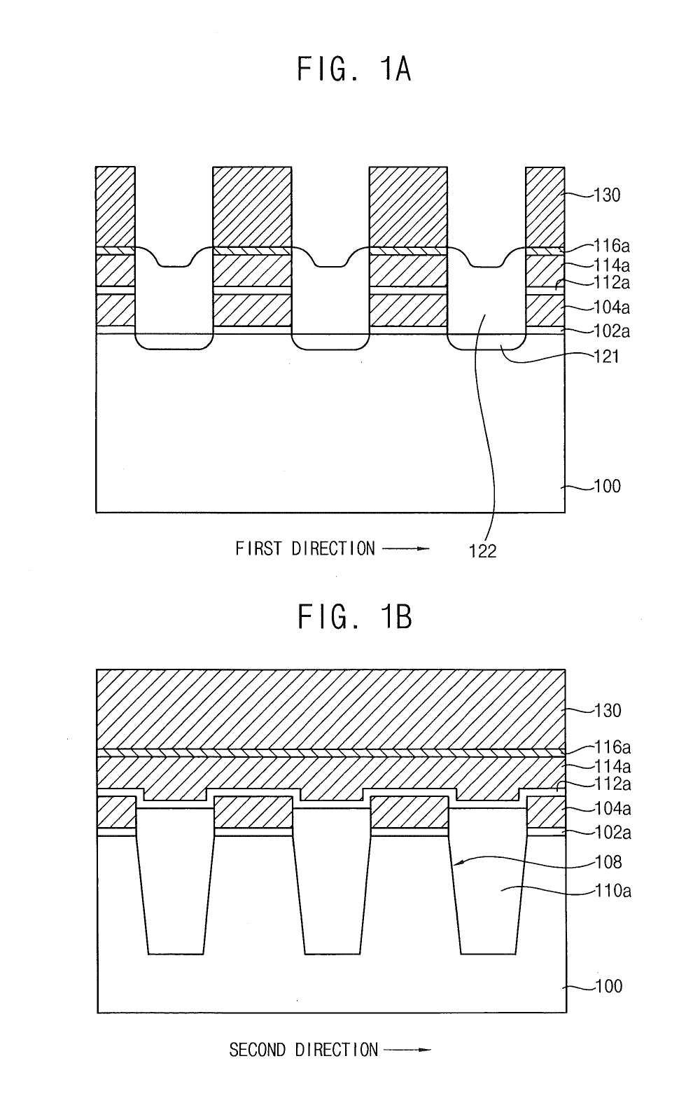

FIGS. 1A and 1B are cross-sectional views of a non-volatile memory device in accordance with Example Embodiment 1.

FIG. 1A is a cross-sectional view cut along a first direction that is perpendicular with respect to direction in which a gate structure of the non-volatile memory device extends. FIG. 1B is a cross-sectional view cut along a second direction in which the gate structure extends.

Referring to FIGS. 1A and 1B, a substrate 100 including a device isolation layer pattern (not shown) may be provided.

On the substrate 100, a tunnel layer pattern 102a, a charge storing layer pattern 104a and a dielectric layer pattern 112a may be provided.

The tunnel layer pattern 102a may include silicon oxide. The charge storing layer pattern 104a may be a floating gate electrode and/or a charge trapping pattern. For example, the floating gate electrode may be formed using impurity doped polysilicon. The charge trapping pattern may include a layer including silicon nitride and/or metal nano-particles, and/or metal oxide including a large amount of charge storing traps.

The dielectric layer pattern 112a may be an insulating interlayer between the charge trapping pattern and a control gate. For example, the dielectric layer pattern 112a may have an ONO (oxide/nitride/oxide) structure including a lower oxide layer, a nitride layer and an upper oxide layer. Alternatively, the dielectric layer pattern 112a may include a metal oxide, such as aluminum oxide, in accordance with another example embodiment. For example, the dielectric layer pattern 112a as the insulating interlayer may include a silicon oxide layer and may further include an aluminum oxide layer between the charge trapping pattern and the control gate.

On the dielectric layer pattern 112a, a first control gate pattern 114a including polysilicon may be formed. The first control gate pattern 114a may function to apply charges to the underlying charge storing layer pattern 104a through the dielectric layer pattern 112a. The first control gate pattern 114a may include a narrow line width of about 20 nm. Alternatively, the first control gate pattern 114a may have a line width lager than 20 nm.

On the first control gate pattern 114a, a first barrier layer pattern 116a for preventing a phase change and a second control gate pattern 130 may be provided. The first barrier layer pattern 116a for preventing the phase change may function to restrain the change of the phase of the second control gate pattern 130 to a material having a high resistance. In particular, the first barrier layer pattern 116a may restrain the phase change of NiSi included in the second control gate pattern 130 to NiSi₂ having a high resistance after performing a thermal process in subsequent processes. Since the first barrier layer pattern 116a may be used as the control gate electrode, a conductive material having a good adhesiveness to an upper layer may be applied for forming the first barrier layer pattern 116a.

The first barrier layer pattern 116a may have a thickness of about 50 angstoms to about 150 angstoms. When the thickness of the first barrier layer pattern 116a is smaller than about 50 angstoms, the phase change of the upper layer may be inadequately restrained, and when the thickness of the first barrier layer pattern 116a is larger than about 150 angstoms, the total resistance of the control gate electrode may increase to an unacceptable level.

The first barrier layer pattern 116a may include a metal, such as tungsten (W), titanium (Ti) and/or tantalum (Ta), and/or a metal compound such as cobalt titanium (CoTi), nickel platinum (NiPt), titanium nitride (TiN), tantalum nitride (TaN) and a silicide compound like cobalt silicide (CoSi₂), tungsten silicide (WSiₓ), molybdenum silicide (MoSiₓ), platinum silicide (PtSiₓ), titanium silicide (TiSiₓ) and/or nickel cobalt silicide (NiCoSiₓ). In the chemical formula, x may represent a real number. These compounds may be used alone or in combination thereof.

On the first barrier layer pattern 116a, the second control gate pattern 130 including NiSi may be formed. The line width of the second control gate pattern 130 may be about 90% to about 110% of the line width of the underlying first control gate pattern 114a. The difference of the line width between the second control gate pattern 130 and the first control gate pattern 114a may be very small, which is within about 10%. Further, since a sidewall profile of the second control gate pattern 130 may be nearly vertical, a difference of the line width of the second control gate pattern 130 according to a position may be rarely generated. As the result, the second control gate pattern 130 may have a narrow line width of about 20 nm.

A blocking layer 122 may be formed on sidewalls of the tunnel layer pattern 102a, the charge storing layer pattern 104a, the dielectric layer pattern 112a and the first control gate pattern 114a. The blocking layer 122 may include silicon oxide and/or silicon nitride. The blocking layer 122 may fill up the gap between integrated structures of the tunnel layer pattern 102a, the charge storing layer pattern 104a, the dielectric layer pattern 112a and the first control gate pattern 114a. The blocking layer 122 may be formed using an insulating material having a good step coverage. Alternatively, the blocking layer 122 may be formed at the upper portion of the gap from the dielectric layer pattern 112a while forming a cavity under the dielectric layer pattern 112a.

An impurity doped region 121 may be formed in the substrate 100 under the gap and between the integrated gate structures of the tunnel layer pattern 102a, the charge storing layer pattern 104a, the dielectric layer pattern 112a, the first control gate pattern 114a, the first barrier layer pattern 116a and the second control gate pattern 130.

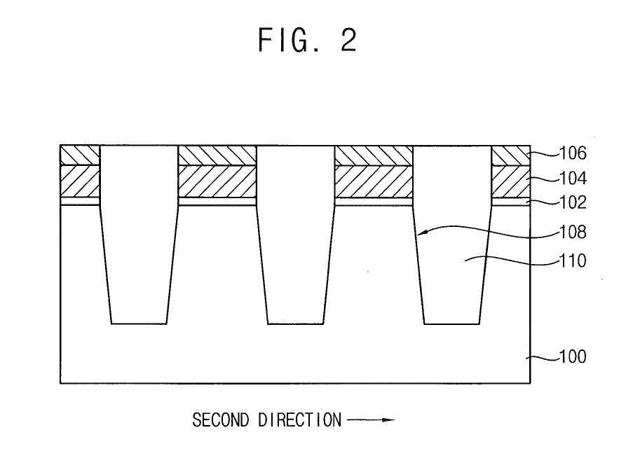

FIGS. 2 to 9 are cross-sectional views for explaining a method of manufacturing a non-volatile memory device in accordance with Example Embodiment 1.

FIGS. 2 to 5 are cross-sectional views cut along the second direction. FIGS. 6 to 9 are cross-sectional views cut along the first direction.

Referring to FIG. 2, a tunnel oxide layer (not shown) and a charge storing layer (not shown) are sequencially formed on a substrate 100.

The substrate 100 may be a semiconductor substrate including silicon or germanium, a silicon-on-insulator (SOI) substrate or a germanium-on-insulator (GOI) substrate. The tunnel oxide layer may be formed by thermally oxidizing a surface portion of the substrate 100 by means of a thermal oxidation process.

The charge storing layer may be a floating gate layer or a charge trapping layer. When the charge storing layer is the floating gate layer, polysilicon may be deposited to form a polysilicon layer. When the charge storing layer is the charge trapping layer, silicon nitride or metal oxide may be deposited to form a silicon nitride layer or a metal oxide layer, or nano-particles may be applied.

On the charge storing layer, a first hard mask pattern 106 may be formed. The first hard mask pattern 106 may have a line shape extending in the first direction. The charge storing layer, the tunnel oxide layer and the substrate 100 may be etched using the first hard mask pattern 106 as an etching mask. Through the above-described process, a preliminary tunnel layer pattern 102 and a preliminary charge storing layer pattern 104 may be formed. A trench 108 may be formed in the device isolation region of the substrate 100.

An insulating layer filling up an inner portion of the trench 108 and a gap between the preliminary charge storing layer patterns 104 may be formed. The insulating layer may include tetraethylorthosilicate (TEOS), un-doped silicate glass (USG), silicon-on-glass (SOG) and/or an oxide such as high-density plasma chemical vapor deposition (HDP CVD) oxide. After forming the insulating layer, a device isolation layer 110 may be formed by polishing the insulating layer by performing a chemical mechanical polishing process until an upper surface of the first hard mask pattern 106 may be exposed.

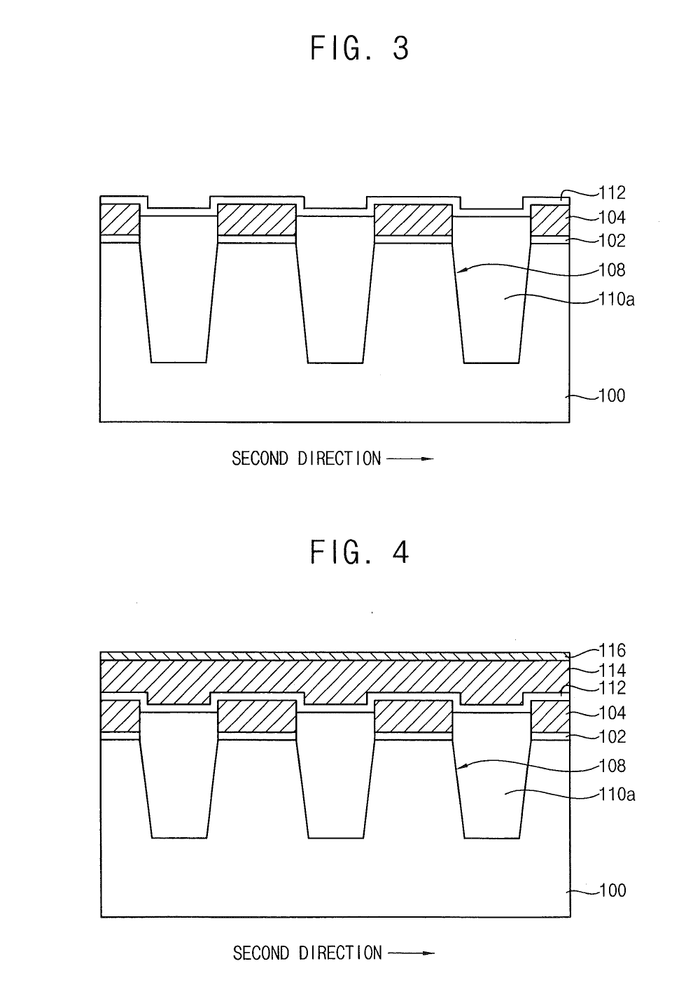

Referring to FIG. 3, the first hard mask pattern 106 may be removed so that an upper surface of the preliminary charge storing layer pattern 104 may be exposed.

A portion of the upper portion of the device isolation layer 110 may be removed to form a device isolation layer pattern 110a so that a portion of a sidewall of the preliminary charge storing layer pattern 104 may be exposed. When the sidewall of the preliminary charge storing layer pattern 104 is exposed, a contact area with a dielectric layer to be formed in a following process may be increased. However, when the thickness of the preliminary charge storing layer pattern 104 is very small and controlling of an etching process to expose the portion of the sidewall of the preliminary charge storing layer pattern 104 is difficult, or to simplify the process, the process of removing the upper portion of the device isolation layer 110 may be omitted.

A dielectric layer 112 may be formed on the preliminary charge storing layer pattern 104 and a device isolation layer pattern 110a.

In accordance with some embodiments, the dielectric layer 112 may be formed to include an ONO structure including a lower oxide layer, a nitride layer and an upper oxide layer.

In accordance with further embodiments, the dielectric layer 112 may be formed using metal oxide having a high dielectricity in order to prevent a generation of a leakage current from the dielectric layer while maintaining a thin equivalent oxide layer thickness (EOT) of the dielectric layer 112. For example, the dielectric layer 112 may be formed using aluminum oxide (AlOₓ), hafnium oxide (HfOₓ), lanthanum oxide (LaOₓ), yttrium oxide (YOₓ), cerium oxide (CeOₓ), titanium oxide (TiOₓ), zirconium oxide (ZrOₓ), silicon oxide (SiOₓ), silicon nitride (SiNₓ), etc. In the chemical formula, x may represent a real number. These compounds may be used alone or in combination thereof.

The dielectric layer 112 may be formed by an atomic layer deposition (ALD) process, a chemical vapor deposition (CVD) process, a low pressure chemical vapor deposition (LPCVD) process, a pulse laser deposition (PLD) process, a sputtering process, a vacuum deposition process, etc.

Referring to FIG. 4, a first polysilicon layer 114 may be formed on the dielectric layer 112. The first polysilicon layer 114 may be an n-type or a p-type impurity doped layer. The first polysilicon layer 114 may be formed by a low pressure chemical vapor deposition process using a deposition gas such as silane (SiH₄), silane (SiH₄) along with an n-type impurity supplying material such as phosphine (PH₃), or silane (SiH₄) along with a p-type impurity supplying material such as boron trihydride (BH₃, % H₆).

A barrier layer 116 may be formed on the first polysilicon layer 114. The barrier layer 116 may function as a portion of a control gate electrode and so may be formed using a conductive material. The barrier layer 116 may prevent or reduce migration of silicon from the first polysilicon layer 114 to an upper material to be formed on the barrier layer 116 and undergoing a phase change as a result. Accordingly, the barrier layer 116 may restrain or inhibit NiSi included in the second control gate pattern from changing phase to NiSi₂, which has a higher resistance than NiSi, due to an excessive amount of silicon provided from the underlying first polysilicon layer 114. The barrier layer 116 may have a thickness of about 50 angstoms to about 150 angstoms.

The barrier layer 116 may be formed using a metal such as tungsten (W), titanium (Ti) and tantalum (Ta), metal compounds like cobalt titanium (CoTi), nickel platinum (NiPt), titanium nitride (TiN), tantalum nitride (TaN) and silicon nitride (SiN), and/or silicides such cobalt silicide (CoSi₂), tungsten silicide (WSiₓ), molybdenum silicide (MoSiₓ), platinum silicide (PtSiₓ), titanium silicide (TiSiₓ) and nickel cobalt silicide (NiCoSiₓ). In the chemical formula, x may represent a real number. These compounds may be used alone or in combination thereof.

In accordance with some embodiments, the barrier layer 116 may include tungsten silicide (WSiₓ).

The tungsten silicide (WSiₓ) layer may be formed by an ALD process, a CVD process, an LPCVD process, a PLD process, a sputtering process, a vacuum deposition process, etc.

The tungsten silicide (WSiₓ) layer may be formed by the CVD process using tungsten hexafluoride (WF₆) as a first source gas and dichlorosilane (SiH₂Cl₂) and/or silane (SiH₄) as a second source gas.

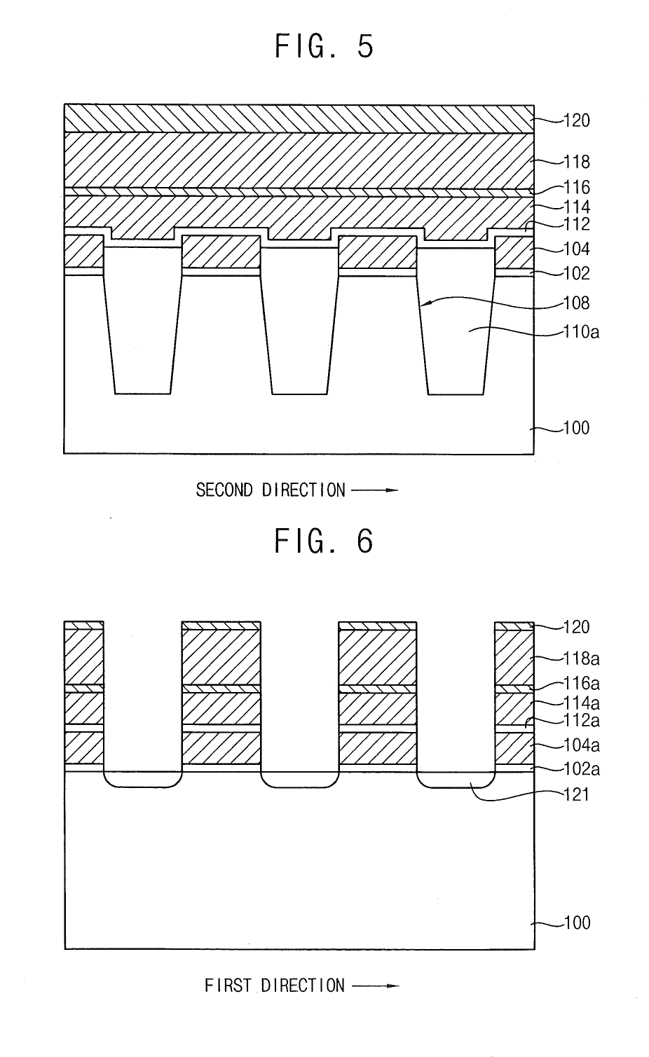

Referring to FIG. 5, a second polysilicon layer 118 may be formed on the barrier layer 116. The second polysilicon layer 118 may be formed by an ALD process, a CVD process, an LPCVD process, an ultrahigh vacuum chemical vapor deposition (UHVCVD) process, a PLD process, etc.

In accordance with example embodiments, the second polysilicon layer 118 may be formed by the LPCVD process using silane (SiH₄) or disilane (Si₂H₆) as a source gas.

Then, a second hard mask pattern 120 may be formed on the second polysilicon layer 118. The second hard mask pattern 120 may be formed by using medium temperature oxide (MTO), plasma enhanced oxide (PE-OX), silicon nitride, etc. The second hard mask pattern 120 may have a line shape extended in the second direction that may be perpendicular to the first direction. That is, the second hard mask pattern 120 may be provided perpendicular to an extending direction of the device isolation layer pattern 110a.

FIGS. 6 to 9 are cross-sectional views cut along the first direction and will be described hereinafter.

Referring to FIG. 6, the second polysilicon layer 118, the barrier layer 116, the first polysilicon layer 114, the dielectric layer 112, the preliminary charge storing layer pattern 104 and the preliminary tunnel layer pattern 102 may be formed by an anisotropic etching process using the second hard mask pattern 120 as an etching mask.

Through the etching process, a preliminary gate structure including a tunnel layer pattern 102a, a charge storing layer pattern 104a, a dielectric layer pattern 112a, a first control gate pattern 114a, a first barrier layer pattern 116a and a second polysilicon pattern 118a may be formed on the substrate 100. The first control gate pattern 114a and the second polysilicon pattern 118a included in the preliminary gate structure may have a narrow line width of about 20 nm.

After forming the preliminary gate structure, impurities may be doped into the surface of the substrate 100 between the preliminary gate structures to form an impurity doped region 121.

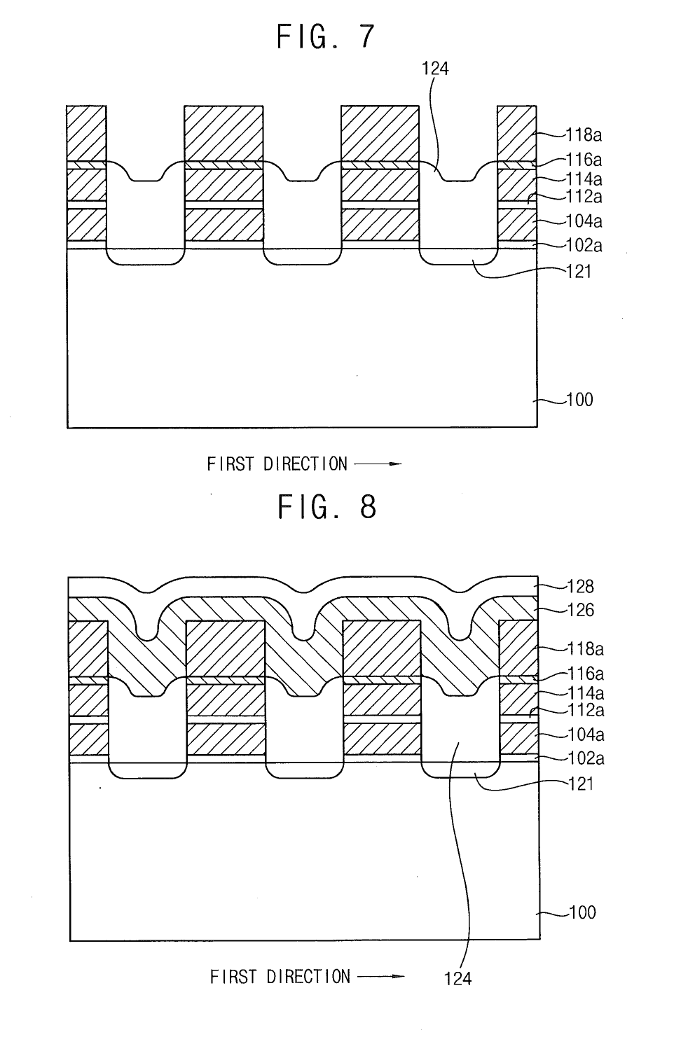

Referring to FIG. 7, an insulating layer (not shown) may be formed between the preliminary gate structures and on the preliminary gate structures to prevent silicidation. The insulating layer may be formed using silicon oxide or silicon nitride. Since the line width of the preliminary gate structure may be very small, the insulating layer may have a shape of filling up a gap between the preliminary gate structures. Alternatively, the insulating layer may have a shape covering the upper portion of the gap with a cavity therein.

A portion of the insulating layer may be etched to form a blocking layer 124 exposing a portion of a sidewall of the preliminary gate structure. The blocking layer 124 may be provided as a silicidation preventing layer. The blocking layer 124 may cover all of the remaining portions except for a portion requiring the silicidation reaction. In particular, the blocking layer 124 may have a shape covering at least the patterns underlying the first barrier layer pattern 116a. Most of the sidewall portion of the second polysilicon pattern 118a may be exposed.

Then, the second hard mask pattern 120 may be removed to expose an upper surface of the second polysilicon pattern 118a. The second hard mask pattern 120 may be removed during a formation of the blocking layer 124.

The surface portion of the exposed second polysilicon pattern 118a may be cleaned. Through the cleaning process, particles and a naturally formed oxide layer may be removed from the surface of the second polysilicon pattern 118a. For example, the cleaning process may include a wet cleaning process using an etching solution including HF or a dry cleaning process. The cleaning process may include a hydrogen baking process. Alternatively, the cleaning process may include a plasma cleaning process including a plasma thermal treatment of hydrogen or a mixture gas of hydrogen and nitrogen.

Referring to FIG. 8, a metal layer, for example, a nickel layer 126, may be formed on the surface of the second polysilicon pattern 118a and on the blocking layer 124. The nickel layer 126 may include pure nickel metal or impurity doped nickel. The nickel layer 126 may be formed by an ALD process, a CVD process, an LPCVD process, a PLD process, a sputtering process, a vacuum deposition process, etc.

The height of the nickel layer 126 may be determined so that the nickel layer 126 may provide a sufficient amount of Ni to react with silicon included in the underlying second polysilicon pattern 118a to form NiSi while performing a subsequent silicidation process. That is, the thickness of the nickel layer 126 may be determined so that the whole second polysilicon pattern 118a may react with the nickel layer 126 to be transformed into NiSi. Generally, silicon included in the second polysilicon pattern having a thickness of about 1.8 anstroms may be consumed per 1 angstrom thickness of the nickel layer to form a NiSi layer. Therefore, the thickness ratio of the nickel layer 126 and the second polysilicon pattern 118a may be about 1:1.8-2.0. For example, when the second polysilicon pattern 118a is formed to a thickness of about 1,100 angstroms, the nickel layer 126 may be formed to a thickness of about 560 angstroms.

A capping layer 128 may be formed on the nickel layer 126. The capping layer 128 may be provided to reduce or prevent a natural oxidation of the nickel layer 126 while performing the heat treatment for the silicidation. The capping layer 128 may be formed using metal nitride, such as titanium nitride (TiN) and titanium aluminum nitride (TiAlN).

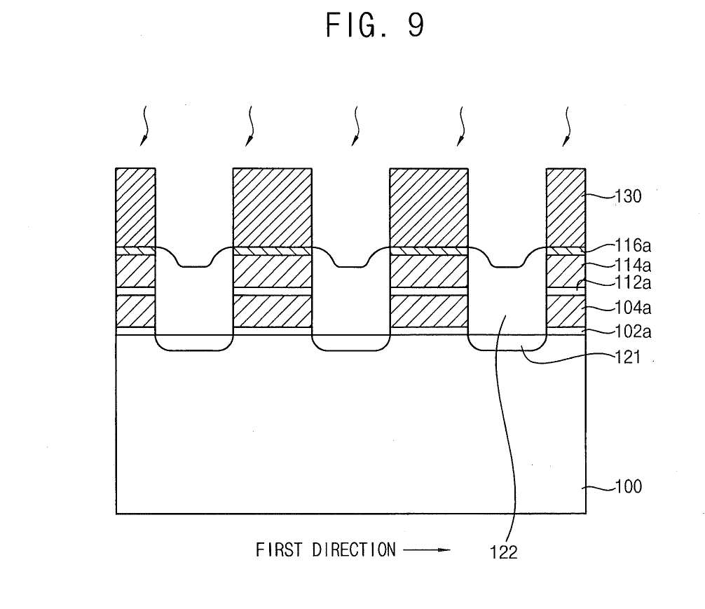

Referring to FIG. 9, the second polysilicon pattern 118a and the nickel layer 126 may be heat treated to form a second control gate pattern 130 including NiSi on the first barrier layer pattern 116a, while restraining the phase change into NiSi₂. Accordingly, the second control gate pattern 130 may include only the NiSi phase excluding the NiSi₂ phase. The heat treatment may be performed one or more times.

In accordance with some embodiments, the heat treatment may be performed once at a temperature of about 320° C. to about 750° C. The heat treatment may be performed for a sufficient time for changing the whole underlying second polysilicon pattern 118a into the NiSi phase. For example, the heat treatment may be performed for one hour. The layer substantially including only NiSi may be obtained through one application of the heat treatment. Titanium silicide or cobalt silicide may require at least two iterations of the heat treatment. However, the nickel silicide layer may be formed through performing a relatively simple process.

After forming the second control gate pattern 130 through the heat treatment, the capping layer 128 may be removed. Further, the unreacted nickel layer 126 may be removed. The unreacted nickel layer 126 may be removed by using a mixture solution of sulfuric acid (H₂SO₄) and hydrogen peroxide (H₂O₂). The nickel layer 126 and the capping layer 128 may be removed simultaneously.

In accordance with some embodiments, the heat treatment may be performed two or more times. In this case, the first heat treatment may be performed at a temperature of about 250° C. to about 350° C. to form a preliminary second control gate pattern (not shown). The preliminary second control gate pattern may include Ni₂Si and NiSi. Then, the unreacted nickel layer 126 may be removed. The capping layer 128 may be also removed. A second heat treatment may be performed with respect to the preliminary second control gate pattern at a temperature of about 400° C. to about 650° C. The preliminary second control gate pattern may be changed to the second control gate pattern 130 including NiSi by the second heat treatment. The second heat treatment may be performed for a sufficient time so that nickel silicide included in the preliminary second control gate pattern may be completely converted to NiSi. The second heat treatment may be performed within 10 minutes and may last for 0.01 second or more.

In accordance with some embodiments, a first heat treatment may be performed at a temperature of about 250° C. to about 350° C. to form a preliminary second control gate pattern. A second heat treatment may be performed at a temperature of about 400° C. to about 650° C. to change the preliminary second control gate pattern into a second control gate pattern 130 including NiSi. Then, the capping layer 128 may be removed and the unreacted nickel layer 126 may be removed.

Referring to FIG. 8 again, the nickel layer 126 may be continuously formed on the sidewall and upper surface of the second polysilicon pattern 118a. Accordingly, the second control gate pattern 130 including NiSi may be formed through a reaction of the nickel layer 126 with the second polysilicon pattern 118a at the sidewall and the upper surface thereof. Since a contacting area of the nickel layer 126 and the polysilicon pattern may become large, the heat treating time for the silicidation may be decreased and the second control gate pattern 130 having a sufficiently high quality may be formed. Further, the second control gate pattern 130 formed through the silicidation reaction at the sidewall and the upper portion of the second polysilicon pattern 118a may have a good morphology characteristic and a nearly vertical sidewall profile.

Then, an insulating interlayer depositing process and a wiring process may be performed even though not shown in the drawing. These following processes may be performed at a high temperature of about 650° C. or higher. Even though the following processes may be performed at the high temperature, NiSi included in the second control gate pattern 130 may not change the phase into the NiSi₂ phase having a relatively higher resistance. The first barrier layer pattern 116a may shield the provision of silicon necessary for the phase change from the first control gate pattern 114a. Therefore, the resistance of the second control gate pattern 130 may not change even after performing the following processes at the high temperature.

Generally, metal silicides used as a gate electrode of a non-volatile memory device may include titanium silicide (TiSi₂), cobalt silicide (CoSi₂), etc. For titanium silicide (TiSi₂), Si consuming thickness ratio with respect to Ti may be relatively large and the thickness consuming ratio of Ti and Si may be about 1:2.3. TiSi₂ may have a lower etching selectivity than NiSi and have a high reactivity with impurities. In addition, TiSi₂ may not generate core in a narrow line width and have a low thermal stability and may not applicable as a gate electrode.

Cobalt silicide (CoSi₂) may have a low dependence on critical dimension (CD) of a gate electrode, have a low specific resistance of about 16 to 18 μΩcm and have an advantage of maintaining a low resistance state at a relatively high temperature. However, CoSi₂ also have a large Si consuming thickness ratio with respect to Co and the thickness consuming ratio of Co and Si may be about 1:3.6. When Co reacts with Si to form CoSi₂, constituting elements may rearrange to reduce a surface energy and an interface energy. Therefore, the CoSi₂ layer may not have a vertical sidewall profile but may have a peanut-shaped sidewall profile. The line width of CoSi₂ may be narrower than an initial silicon line width and CoSi₂ may not applicable as a gate electrode of a highly integrated non-volatile memory device. That is, when forming a non-volatile memory device including a gate structure having about 20 nm line width, a pattern portion having a line width less than 10 nm may be formed due to CoSi₂. In this case, the pattern portion may be broken and/or may have a high resistance.

In accordance with some embodiments, the second control gate pattern 130 including NiSi may have a low specific resistance of about 16 to 18 μΩcm. The Si consuming thickness ratio with respect to Ni of NiSi may be relatively smaller than that with respect to Ti or Co of TiSi₂ or CoSi₂.

The second control gate pattern 130 including NiSi may not undergo a phase change into NiSi₂ in a subsequent heat treatment process. Accordingly, the thermal stability of a gate structure may be improved. In particular, when tungsten silicide is used as the first barrier layer pattern 116a, the phase change of NiSi into NiSi₂ may be restrained even though a thermal budget of about 900° C. or higher may be applied in a subsequent process. The resistance of the second control gate pattern 130 may thereby be more stable.

As described above, the second control gate pattern 130 including NiSi may have a good morphology characteristic and may have a nearly vertical sidewall profile. Accordingly, the line width of the second control gate pattern 130 may be almost the same as that of the underlying first control gate pattern 114a. The second control gate pattern 130 including NiSi may be applicable to a highly integrated non-volatile memory device having a line width of about 20 nm.

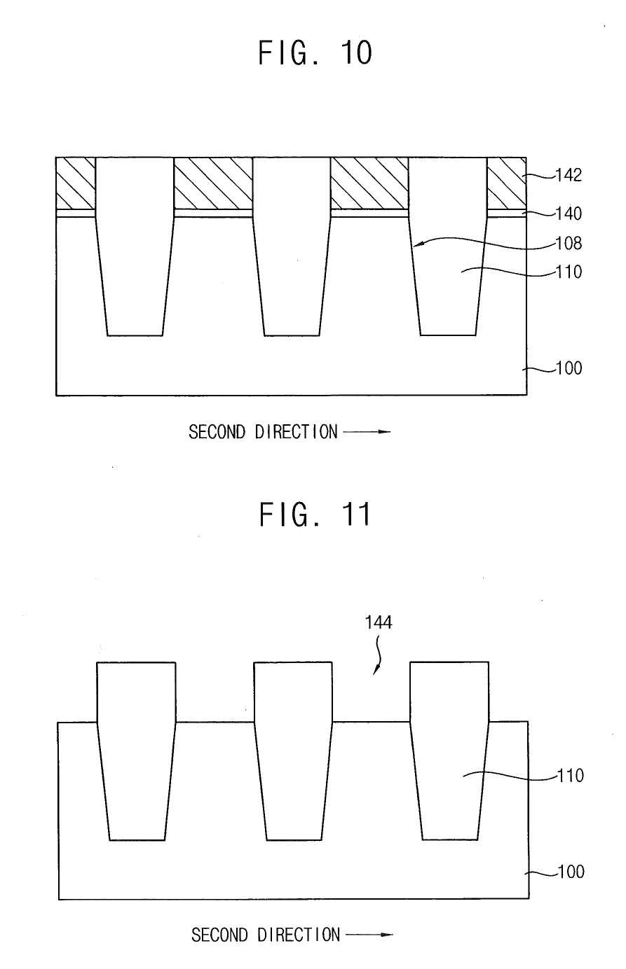

FIGS. 10 to 12 are cross-sectional views for explaining methods of manufacturing a non-volatile memory device illustrated in FIG. 1 according to further embodiments.

FIGS. 10 to 12 are cross-sectional views cut along the second direction.

Referring to FIG. 10, a buffer oxide layer (not shown) and a first mask layer (not shown) may be formed one by one on a substrate 100. A buffer oxide layer pattern 140 and a first mask pattern 142 may be formed through performing a photolithography process with respect to the first mask layer and the buffer oxide layer.

In accordance with some embodiments, the buffer oxide layer may be formed by thermally oxidizing a surface portion of the substrate 100 through a thermal oxidation process. The buffer oxide layer also may be formed by depositing oxide on the semiconductor substrate 100 through a CVD process. The buffer oxide layer may include silicon oxide.

The first mask layer may be formed by an LPCVD process, a PECVD process or an ALD process. The first mask layer may be formed using a material having an etching selectivity with respect to the buffer oxide layer and the substrate 100. For example, the first mask layer may be formed using silicon nitride or silicon oxynitride.

Trenches 108 may be formed to define active regions and device isolation regions in the substrate 100 by partially etching the substrate 100 using the first mask pattern 142 as an etching mask.

An insulating layer may be formed on the first mask pattern 142 while filling up the trenches 108. The insulating layer may be polished until the first mask pattern 142 is exposed to form device isolation layers 110 filling up the trenches 108. The insulating layer may be formed by using one of a CVD process, a PECVD process, an HDP-CVD process and an ALD process. The insulating layer may be formed using borophosphosilicate glass (BPSG), phosphosilicate glass (PSG), undoped silicate glass (USG), spin-on-glass (SOG), field oxide (FOX), tetraethyl orthosilicate (TEOS), plasma enhanced-TEOS (PE-TEOS) and HDP-CVD oxide.

The device isolation layers 110 may have substantially the same height as the first mask pattern 142 and may protrude above the substrate 100. The device isolation layers 110 may be provided to form a charge storing layer pattern through a following self aligned polysilicon (SAP) process.

Referring to FIG. 11, the first mask pattern 142 and the buffer oxide layer pattern 140 may be removed. Then, an opening 144 may be formed between the device isolation layers 110 and the substrate 100 may be exposed through the opening 144.

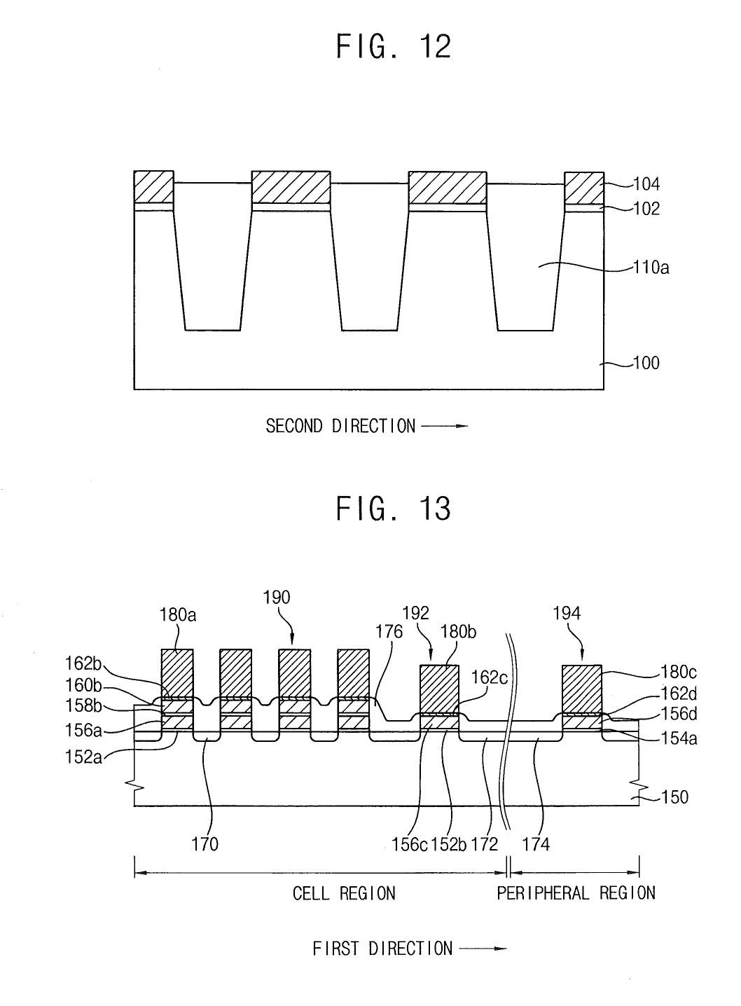

Referring to FIG. 12, a preliminary tunnel layer pattern 102 may be formed on the surface of the substrate 100 and at the bottom of the opening 144.

In accordance with some embodiments, the preliminary tunnel layer pattern 102 may be formed by a thermal oxidation process for oxidizing the surface portion of the substrate 100. Alternatively, the preliminary tunnel layer pattern 102 may be formed by depositing oxide or metal oxide on the active regions using a CVD process, an LPCVD process, a PECVD process or an ALD process. A nitration process using a plasma including nitrogen may be further implemented for the preliminary tunnel layer pattern 102.

A charge storing layer may be formed on the preliminary tunnel layer pattern 102 and the device isolation layers 110. The charge storing layer may fill up the openings formed between the device isolation layers 110.

The charge storing layer may be etched or chemically mechanically polished until the upper surface of the device isolation layer 110 may be exposed to form a preliminary charge storing layer pattern 104.

An upper portion of the device isolation layer may be partially removed to expose a portion of the sidewall of the preliminary charge storing layer pattern 104 to form a device isolation layer pattern 110a.

On the preliminary charge storing layer pattern 104, a dielectric layer may be formed. After forming the dielectric layer, the same structure illustrated in FIG. 3 may be obtained.

Similar processes may be performed as described referring to FIGS. 4 to 9. A non-volatile memory device illustrated in FIG. 1 may thereby be formed.

### Example Embodiment 2

FIG. 13 is a cross-sectional view of a non-volatile memory device in accordance with Example Embodiment 2.

FIG. 13 is a cross-sectional view cut along the first direction.

Referring to FIG. 13, a cell region and a peripheral circuit region may be provided in a substrate 150. In the cell region of the substrate 150, cell strings including cell transistors 190 and selecting transistors 192 connected in series and disposed at both sides of the cell transistors 190 may be provided. In the peripheral circuit region, transistors 194 for peripheral circuits may be formed. In the cell region and the peripheral circuit region of the substrate 150, a device isolation layer (not shown) may be provided and an active region and a device isolation region may be separated by the device isolation layer.

The cell transistors 190 may have the same structure as explained referring to FIG. 1. In accordance with Example Embodiment 2, a charge storing layer pattern 156a included in the cell transistor may be formed using polysilicon. The cell transistors 190 may include a cell gate structure including a tunnel layer pattern 152a, a charge storing layer pattern 156a, a dielectric layer pattern 158b, a first control gate pattern 160b, a first barrier layer pattern 162b and a second control gate pattern 180a, and a first impurity doped region 170 at both sides of the cell gate structure in the substrate.

The selecting transistors 192, including a string selecting transistor (SSL) and a ground selecting transistor (GSL), provided at both end portions of the cell transistors 190, may include a gate structure including an integrated structure of a first gate oxide layer pattern 152b, a first gate electrode 156c, a second barrier layer pattern 162c and a second gate electrode 180b. A second impurity doped region 172 may be provided at both sides of the selecting gate structure in the substrate 150.

The selecting gate structure may have a relatively wider line width than the gate structure included in the cell transistor. The first gate electrode 156c may be formed using polysilicon. The second barrier layer pattern 162c may be formed using the same material of the first barrier layer pattern 162b included in the cell transistor. The first and second barrier layer patterns 162b and 162c may have the same thickness. The second gate electrode 180b may be formed using the same material used for forming the second control gate pattern 180a included in the cell transistor. For example, the second gate electrode 180b may be formed using NiSi. The second gate electrode 180b and the second control gate pattern 180a may have the same thickness.

The difference of a line width of the second gate electrode 180b and that of the underlying first gate electrode 156c may be very small, e.g. within about 10%. The second gate electrode 180b may have a nearly vertical sidewall profile and the line width difference according to the position of the second gate electrode 180b may be small.

In the peripheral circuit region of the substrate 150, transistors for the peripheral circuits may be formed. The transistor for the peripheral circuits may include a gate structure for the peripheral region having an integrated structure of a second gate oxide layer pattern 154a, a third gate electrode 156d, a third barrier layer pattern 162d and a fourth gate electrode 180c. A third impurity doped region 174 may be formed at both sides of the gate structure for the peripheral region in the substrate.

The gate structure for the peripheral circuit region may have a relatively larger line width than the gate structure included in the cell transistor. The third gate electrode 156d may be formed using polysilicon. The third barrier layer pattern 162d may be formed using the same material of the first barrier layer pattern 162b included in the cell transistor. The third and first barrier layer patterns 162d and 162b may have the same thickness. Further, the fourth gate electrode 180c may be formed using the same material of the second control gate pattern 180a included in the cell transistor. The fourth gate electrode 180c and the second control gate pattern 180a may have the same thickness.

The difference of a line width of the fourth gate electrode 180c and that of the underlying third gate electrode 156d may be very small, e.g. within about 10%. The fourth gate electrode 180c may have a nearly vertical sidewall profile and the line width difference according to the position of the fourth gate electrode 180c may be small.

An insulating layer 176 for blocking may be formed in gaps between the cell gate structure, the selecting gate structure and the peripheral gate structure. The insulating layer 176 for blocking may be formed using silicon oxide. The insulating layer 176 for blocking may have a shape covering the sidewall of the patterns underlying the first to third barrier layer patterns 162b, 162c and 162d.

As illustrated in FIG. 13, the gate electrodes of the selecting transistor and the peripheral transistor may include the barrier layer pattern and NiSi having a low resistance. Accordingly, the non-volatile memory device in accordance with Example Embodiment 2 may have a highly integrated structure and be operated at a high speed.

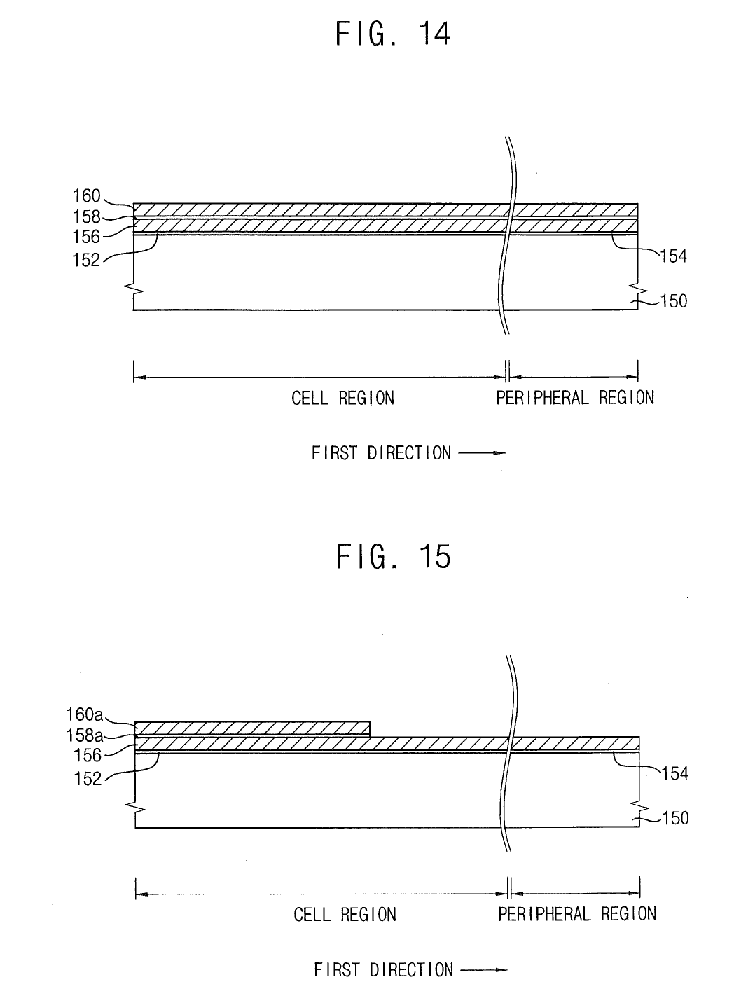

FIGS. 14 to 17 are cross-sectional views for explaining a method of manufacturing a non-volatile memory device in accordance with Example Embodiment 2.

FIGS. 14 to 17 are cross-sectional views cut along the first direction.

Referring to FIG. 14, a first oxide layer may be formed in the cell region of the substrate 150. A second oxide layer may be formed in the peripheral circuit region of the substrate 150. The first and second oxide layers may be formed by performing thermal oxidation processes separately. Therefore, the first and second oxide layers may have different thicknesses.

A lower polysilicon layer may be formed on the first and second oxide layers. The lower polysilicon layer may serve as a floating gate electrode in the cell region and may serve as a first gate electrode in the peripheral region.

On the lower polysilicon layer, a first hard mask pattern (not shown) may be formed and a trench (not shown) may be formed by etching the lower polysilicon layer, the first and second oxide layers and a portion of the substrate using the first hard mask pattern as an etching mask. A first oxide layer pattern 152 and a lower polysilicon layer pattern 156 may be integrated in the cell region of the substrate 150 and a second oxide layer pattern 154 and a lower polysilicon layer pattern 156 may be integrated in the peripheral circuit region of the substrate 150. Then, a device isolation layer (not shown) may be formed within the trench. The process for forming the device isolation layer may be substantially the same as described referring to FIG. 2.

The first hard mask pattern may be removed to expose a surface portion of the lower polysilicon layer pattern 156.

On the lower polysilicon layer pattern 156 and the device isolation layer, a dielectric layer 158 may be formed. On the dielectric layer 158, a first polysilicon layer 160 may be formed. The first polysilicon layer 160 may be provided as a first control gate pattern in a following process.

Referring to FIG. 15, the first polysilicon layer 160 and the dielectric layer 158 disposed in a portion where a selecting transistor may be formed in the cell region may be selectively removed by performing a photolithography process. The first polysilicon layer 160 and the dielectric layer 158 formed in the peripheral circuit region may be selectively removed. A first polysilicon layer pattern 160a and a dielectric layer pattern 158a may be formed in the cell region of the substrate 150.

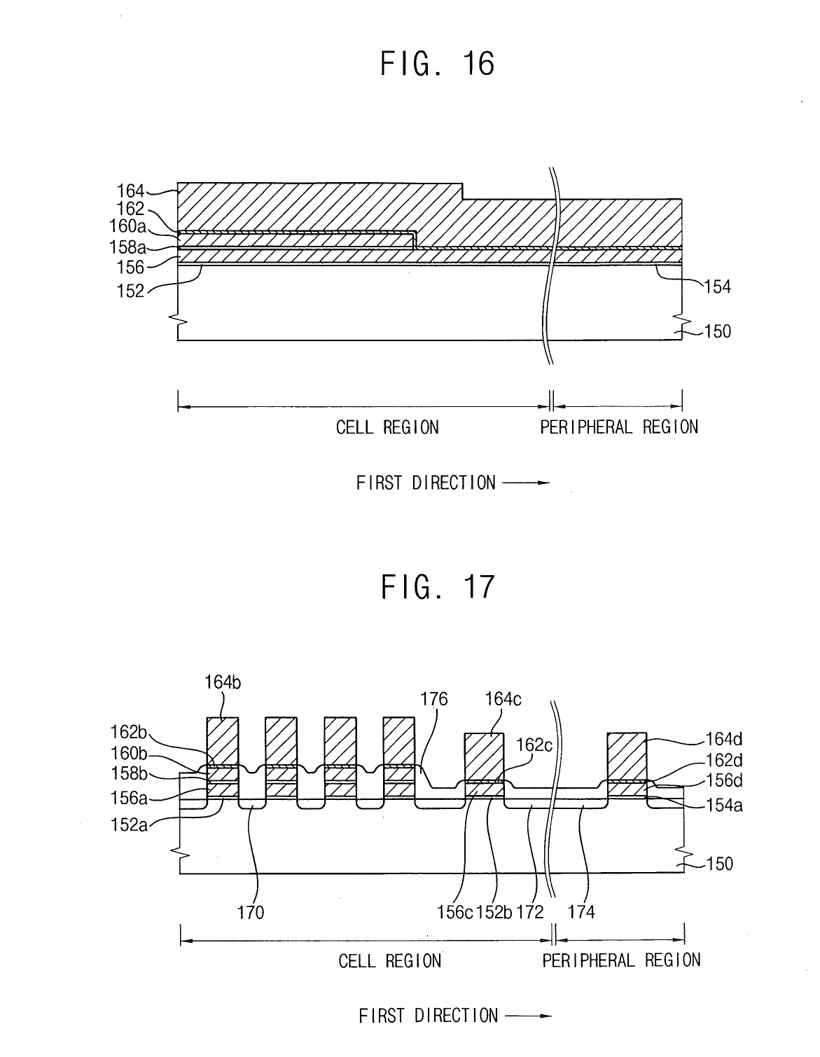

Referring to FIG. 16, a barrier layer 162 may be formed on the first polysilicon layer pattern 160a and the lower polysilicon layer pattern 156.

The barrier layer pattern 162 may include a metal such as tungsten (W), titanium (Ti) and/or tantalum (Ta), and/or a metal compound such as cobalt titanium (CoTi), nickel platinum (NiPt), titanium nitride (TiN), tantalum nitride (TaN) and a silicide compound like cobalt silicide (CoSi₂), tungsten silicide (WSiₓ), molybdenum silicide (MoSiₓ), platinum silicide (PtSiₓ), titanium silicide (TiSiₓ) and nickel cobalt silicide (NiCoSiₓ) as described in Example Embodiment 1. In the chemical formula, x may represent a real number. These compounds may be used alone or in combination thereof.

On the barrier layer 162, a second polysilicon layer 164 may be formed. The whole second polysilicon layer 164 may change into nickel silicide through performing a subsequent silicidation process. Accordingly, the thickness of the second polysilicon layer 164 may be determined considering a target thickness of the nickel silicide to be obtained.

The barrier layer 162 and the second polysilicon layer 164 may be formed by performing substantially the same procedure described referring to FIGS. 4 and 5.

Referring to FIG. 17, a second hard mask pattern (not shown) may be formed on the second polysilicon layer 164. The lower thin films may be etched using the second hard mask pattern as an etching mask.

In the cell region of the substrate 150, a preliminary gate structure including a tunnel layer pattern 152a, a charge storing layer pattern 156a, a dielectric layer pattern 158b, a first control gate pattern 160b, a first barrier layer pattern 162b and a second polysilicon pattern 164b, and a preliminary selecting gate structure including a first gate oxide layer pattern 152b, a first gate electrode 156c, a second barrier layer pattern 162c and a second preliminary gate pattern 164c may be formed. In the peripheral region of the substrate 150, a gate structure for peripheral circuits including a second gate oxide layer pattern 154a, a third gate electrode 156d, a third barrier layer pattern 162d and a fourth preliminary gate pattern 164d may be formed.

A first impurity doped region 170 may be formed by doping impurities into the substrate 150 between the preliminary gate structures. A second impurity doped region 172 may be formed by doping impurities into the substrate 150 between the preliminary selecting gate structures. A third impurity doped region 174 may be formed by doping impurities into the substrate 150 between the preliminary gate structures for peripheral region.

An insulating layer covering the surface of the preliminary gate structures, the preliminary selecting gate structures and the preliminary gate structures for peripheral region and the gap between the structures may be formed.

A portion of the insulating layer may be etched to form a blocking layer 176 exposing a portion of sidewalls of the preliminary gate structures, the selecting gate structures and the gate structures for peripheral circuits. The blocking layer 176 may be formed to cover at least patterns provided under the first to third barrier layer patterns 162b, 162c and 162d included in each gate structure.

Referring to FIG. 13 again, a nickel layer (not shown) may be formed on the surface of the second polysilicon pattern 164b, the second preliminary gate pattern 164c and the fourth preliminary gate pattern 164d and on the blocking layer 176. The forming process may be similar to the process explained referring to FIG. 8.

Through a heat treatment, polysilicon included in the second polysilicon pattern 164b, the second preliminary gate pattern 164c and the fourth preliminary gate pattern 164d and nickel included in the nickel layer may react to form nickel silicide having a NiSi phase. On the first to third barrier layer patterns 162b, 162c and 162d, the second control gate pattern 180a, the second gate electrode 180b and the fourth gate electrode 180c including the NiSi phase may be formed, respectively. The heat treatment may be performed according to the similar process explained referring to FIG. 9.

A non-volatile memory device including a barrier layer pattern and a NiSi phase having a low resistance in a gate electrode of a selecting transistor and a peripheral transistor may be manufactured.

### Example Embodiment 3

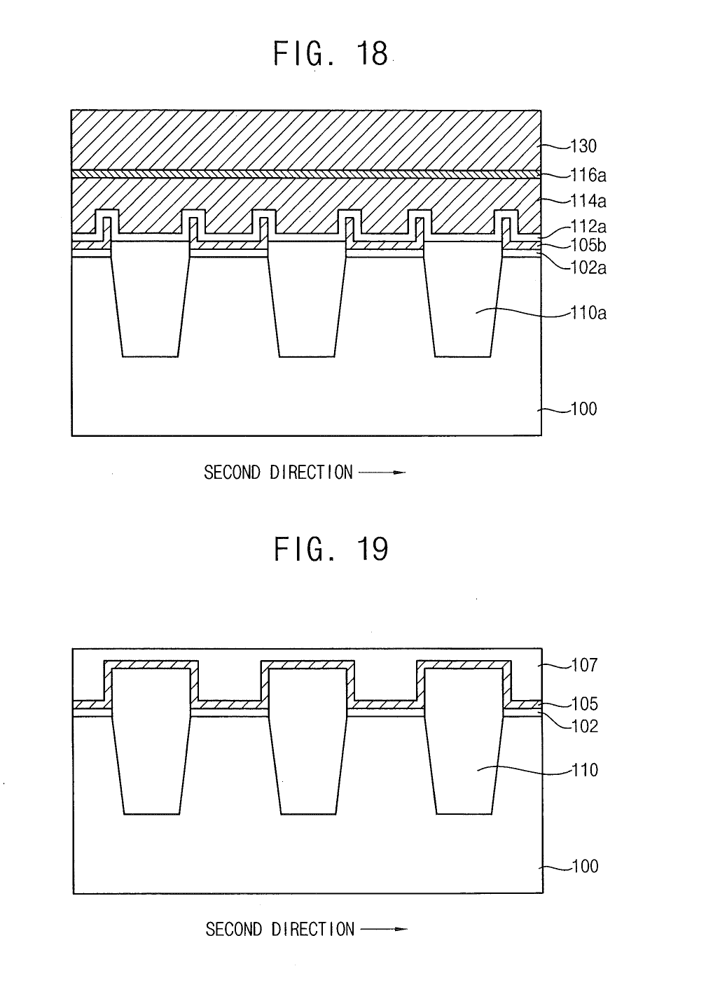

FIG. 18 is a cross-sectional view of a non-volatile memory device in accordance with Example Embodiment 3.

A non-volatile memory device in accordance with Example Embodiment 3 may include a U-shaped charge storing layer pattern. The charge storing layer pattern may be provided as a floating gate electrode. The remaining elements may be the same as or similar to those included in the non-volatile memory device illustrated in FIG. 1.

FIG. 18 is a cross-sectional view cut along the second direction. The cross-sectional view of the non-volatile memory device cut along the first direction in accordance with Example Embodiment 3 may be the same as the device illustrated in FIG. 1, except for a slightly thinner charge storing layer.

Referring to FIG. 18, a substrate 100 including a device isolation layer pattern 110a may be formed. A tunnel layer pattern 102a may be formed on the substrate 100 and a U-shaped floating gate electrode 105b may be formed on the tunnel layer pattern 102a. On the floating gate electrode 105b, a dielectric layer pattern 112a may be provided. The dielectric layer pattern 112a may be formed on the surface profile of the U-shaped floating gate electrode 105b.

A first control gate pattern 114a formed by using polysilicon may be formed on the dielectric layer pattern 112a.

On the first control gate pattern 114a, a first barrier layer pattern 116a for preventing the phase change may be formed. On the first barrier layer pattern 116a, a second control gate pattern 130 including a NiSi phase may be formed. The first barrier layer pattern 116a and the second control gate pattern 130 may include the same elements described in Example Embodiment 1.

FIGS. 19 to 22 are cross-sectional views for explaining a method of manufacturing a non-volatile memory device in accordance with Example Embodiment 3.

Referring to FIG. 19, the same process explained referring to FIGS. 10 and 11 may be performed to form a device isolation layer 110 on the substrate 100 as illustrated in FIG. 11.

On the substrate of the bottom surface of an opening formed between the device isolation layers 110, a preliminary tunnel layer pattern 102 may be formed. A floating gate layer 105 may be formed along the surface profile of the preliminary tunnel layer pattern 102 and the device isolation layer 110. The floating gate layer 105 may be formed using impurity doped polysilicon.

On the floating gate layer 105, a sacrificial layer 107 filling up a gap between the device isolation layers 110 may be formed. The sacrificial layer 107 may be formed using silicon oxide, an organic polymer, etc.

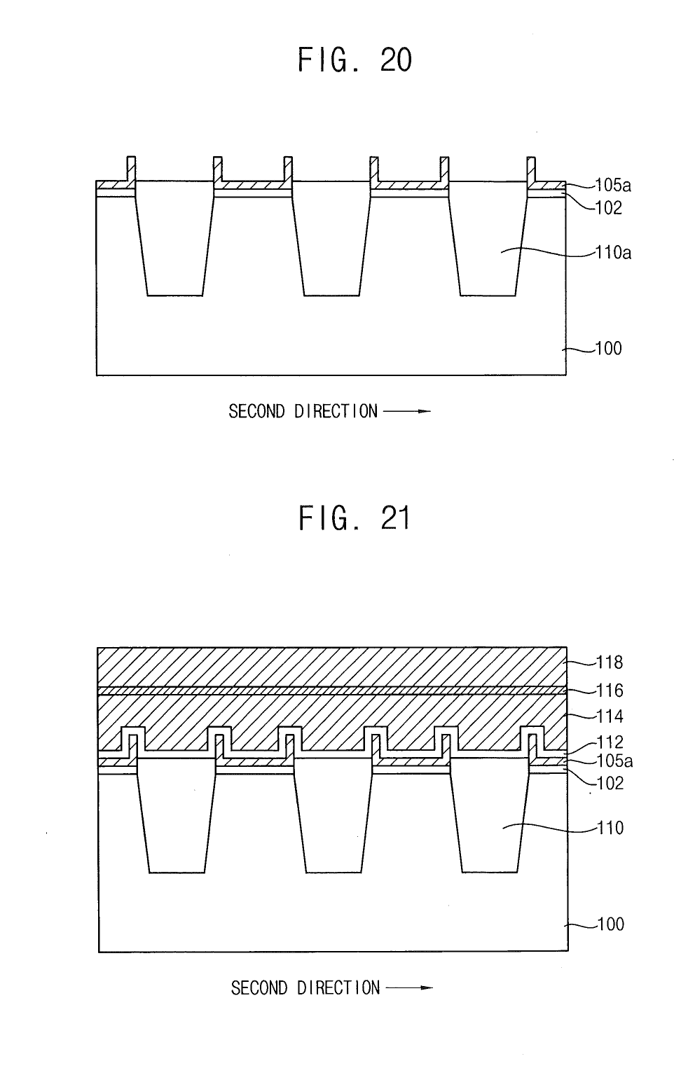

Referring to FIG. 20, a portion of the floating gate layer 105 and the sacrificial layer 107 may be removed until the device isolation layer 110 may be exposed to form a preliminary floating gate pattern 105a. The preliminary floating gate pattern 105a may be formed by a chemical mechanical polishing process and/or an etch back process. The preliminary floating gate pattern 105a may have a U-shape extended in the first direction.

Then, the sacrificial layer 107 may be removed. The upper portion of the device isolation layer 110 may be removed to expose at least a portion of the sidewall of the preliminary floating gate pattern 105a to form a device isolation layer pattern 110a. The removal of the sacrificial layer 107 and the device isolation layer 110 may be performed by an etching process, simultaneously.

Referring to FIG. 21, a dielectric layer 112 may be formed on a preliminary floating gate pattern 105a and a device isolation layer pattern 110a. On the dielectric layer 112, a first polysilicon layer 114 may be formed. After forming the first polysilicon layer 114, a planarization process with respect to the surface of the first polysilicon layer 114 may be further implemented.

On the first polysilicon layer 114, a barrier layer 116 and a second polysilicon layer 118 may be formed.

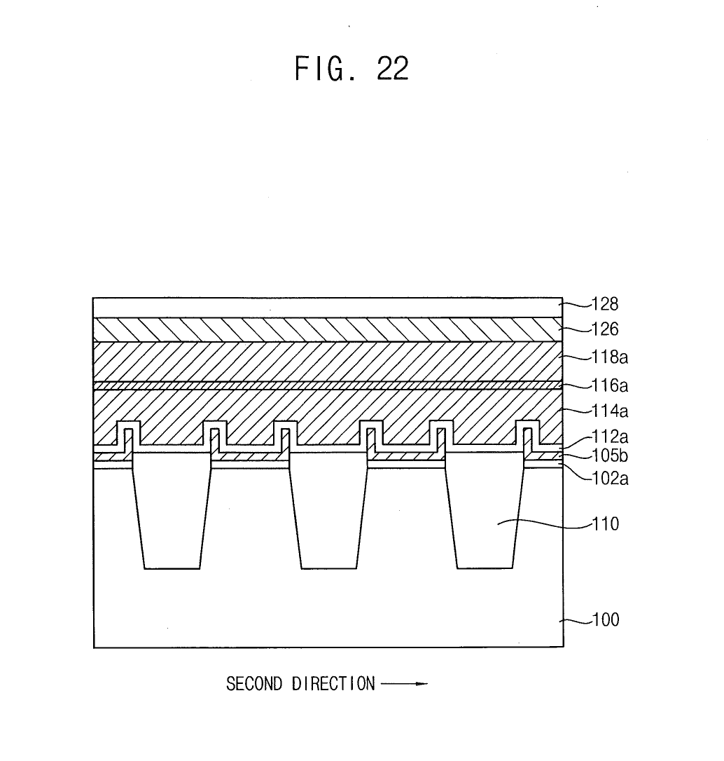

Referring to FIG. 22, a second hard mask pattern (not shown) may be formed on the second polysilicon layer 118. The second polysilicon layer 118, the barrier layer 116, the first polysilicon layer 114, the dielectric layer 112, the preliminary floating gate pattern 105a and the preliminary tunnel layer pattern 102 may be etched using the second hard mask pattern as an etching mask. On the substrate 100, a preliminary gate structure including a tunnel layer pattern 102a, a floating gate pattern 105b, a dielectric layer pattern 112a, a first control gate pattern 114a, a first barrier layer pattern 116a and a second polysilicon pattern 118a may be formed.

On the sidewall of the preliminary gate structure, a blocking layer (not shown) may be formed. The second hard mask pattern may be removed. The upper surface of the second polysilicon pattern 118a may be cleaned.

The patterning process and the forming process of the blocking layer may be the same as described referring to FIGS. 6 and 7. The cross-sectional view of the device obtained at this step and cut along the first direction may be the same as illustrated in FIGS. 6 and 7.

On the second polysilicon pattern 118a, a nickel layer 126 and a capping layer 128 may be formed. The nickel layer 126 and the capping layer 128 may be formed through the same procedure as described referring to FIG. 8.

Referring to FIG. 18 again, the second polysilicon pattern 118a and the nickel layer 126 may be heat treated to form a second control gate pattern 130 including a NiSi phase on the first barrier layer pattern 116a, while restraining the phase change into a NiSi₂ phase. The forming process of the second control gate 130 including the NiSi phase may be substantially the same as described referring to FIG. 9.

Evaluation on Heat Resistance of Conductive Structure 1

In order to compare a heat resistance of conductive structures including a NiSi layer, samples of the conductive structure included in a gate electrode in accordance with example embodiments were manufactured.

### Sample 1

A tungsten silicide layer was formed to a thickness of about 80 angstoms on a single crystalline silicon substrate. On the tungsten silicide layer, a nickel silicide layer was formed to a thickness of about 1,000 angstroms. The heat treatment for forming the nickel silicide layer was performed at a temperature of about 700° C. for about 30 minutes.

### Sample 2

A cobalt silicide layer was formed to a thickness of about 80 angstoms on a single crystalline silicon substrate. On the cobalt silicide layer, a nickel silicide layer was formed with a thickness of about 1,000 angstoms. The heat treatment for forming the nickel silicide layer was performed at a temperature of about 700° C. for about 30 minutes.

### Sample 3

A titanium nitride layer was formed to a thickness of about 80 angstoms on a single crystalline silicon substrate. On the titanium nitride layer, a nickel silicide layer was formed with a thickness of about 1,000 angstroms. The heat treatment for forming the nickel silicide layer was performed at a temperature of about 700° C. for about 30 minutes.

### Comparative Sample 1

A nickel silicide layer was formed to a thickness of about 1,000 angstoms on a single crystalline silicon substrate. The heat treatment for fanning the nickel silicide layer was performed at a temperature of about 700° C. for about 30 minutes.

A heat treatment was performed with respect to Samples 1 to 3 and Comparative Sample 1 at each temperature, and sheet resistances were measured. The sheet resistance of each sample measured after heat treating at a temperature of about 450° C. was normalized to 1 and relative sheet resistance at each heat treating temperature was calculated.

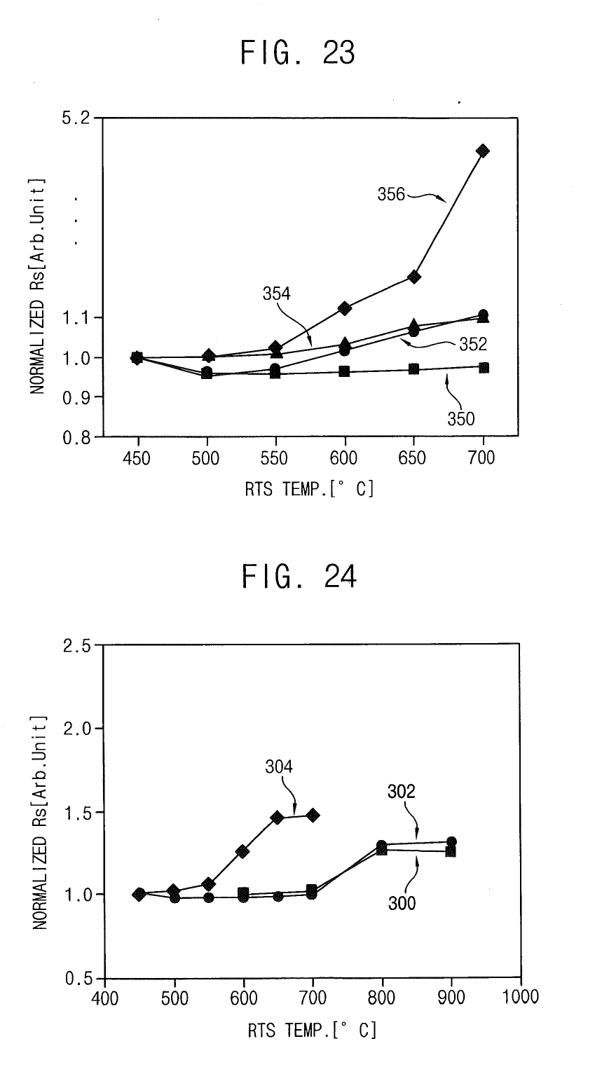

FIG. 23 illustrates a graph representing sheet resistances with respect to heat treating temperatures for Samples 1 to 3 and Comparative Sample 1.

In FIG. 23, graph ‘350’ corresponds to data of Sample 1, graph ‘352’ corresponds to data of Sample 2, graph ‘354’ corresponds to data of Sample 3 and graph ‘356’ corresponds to data of Comparative Sample 1.

Referring to FIG. 23, the sheet resistances increased a little even after heat treating at a temperature of about 700° C. for Samples 1 to 3 including the barrier layer. In particular, when the tungsten silicide layer was used as the barrier layer (Sample 1), the sheet resistance exhibited almost no change after heat treating at a temperature of about 700° C.

However, for the Comparative Sample 1 excluding the barrier layer, the sheet resistance was largely increased after heat treating at a temperature of about 700° C.

Samples 1 to 3 including the barrier layer were evaluated as having good thermal stability.

Evaluation on Heat Resistance of Conductive Structure 2

In order to compare a heat resistance of conductive structures including a tungsten silicide layer as a barrier layer and including a NiSi layer, samples of the conductive structures included in a gate electrode in accordance with example embodiments were manufactured.

### Sample 4

A first polysilicon layer was formed to a thickness of about 340 angstoms on a substrate. On the first polysilicon layer, a tungsten silicide layer was formed to have a thickness of about 80 angstoms. A second polysilicon layer was formed to a thickness of about 1,100 angstoms on the tungsten silicide layer. A nickel layer was formed to a thickness of about 560 angstoms on the second polysilicon layer. Then, a heat treatment was performed at a temperature of about 700° C. for about 30 minutes to form a nickel silicide layer having a thickness of about 1,230 angstoms. That is, the conductive structure of Sample 4 includes the first polysilicon layer, the tungsten silicide layer and the nickel silicide layer.

### Sample 5

A first polysilicon layer was formed to a thickness of about 340 angstoms on a substrate. On the first polysilicon layer, a tungsten silicide layer was formed to have a thickness of about 100 angstoms. A second polysilicon layer was formed to a thickness of about 1,100 angstoms on the tungsten silicide layer. A nickel layer was formed with a thickness of about 560 angstoms on the second polysilicon layer. Then, a heat treatment was performed at a temperature of about 700° C. for about 30 minutes to form a nickel silicide layer having a thickness of about 1,230 angstoms. That is, the conductive structure of Sample 5 includes the same integrated structure as Sample 4 except for the thickness of the tungsten silicide layer.

### Comparative Sample 2

Different from example embodiments, a conductive structure including a gate structure excluding a barrier layer was manufactured.

A first polysilicon layer was formed to a thickness of about 110 angstoms on a substrate. On the first polysilicon layer, a nickel layer was formed to have a thickness of about 200 angstoms. Then, a heat treatment was performed at a temperature of about 700° C. for about 30 minutes to form a nickel silicide layer having a thickness of about 1,230 angstoms. That is, the conductive structure of Comparative Sample 2 includes only the nickel silicide layer on the substrate.

A heat treatment was performed with respect to Samples 4 and 5 and Comparative Sample 2 at each temperature, and sheet resistances were measured. The sheet resistance of each sample measured after heat treating at a temperature of about 450° C. was normalized to 1 and a relative sheet resistance at each heat treating temperature was calculated.

FIG. 24 illustrates a graph representing sheet resistances with respect to heat treating temperatures for Samples 4 and 5 and Comparative Sample 2.

In FIG. 24, graph ‘300’ corresponds to data of Sample 4, graph ‘302’ corresponds to data of Sample 5 and graph ‘304’ corresponds to data of Comparative Sample 2.

Referring to FIG. 24, the sheet resistances were barely increased even after heat treating at a temperature of about 700° C. for Samples 4 and 5. The increase of the sheet resistance was relatively small even after heat treating at a high temperature of about 900° C. or higher for Samples 4 and 5. When the tungsten silicide layer was used as the barrier layer as in Samples 4 and 5, the heat resistance was good.

However, for the Comparative Sample 2 excluding the barrier layer, the sheet resistance was largely increased by about 100% or over after heat treating at a temperature of about 700° C. Comparative Sample 2 was evaluated to have a low thermal stability.

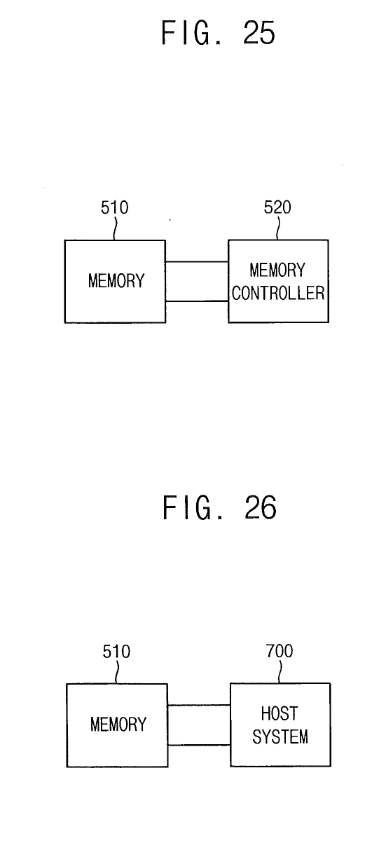

FIG. 25 is a block diagram illustrating an electronic device including a non-volatile memory device in accordance with some embodiments.

Referring to FIG. 25, the electronic device may include a memory 510 connected to a memory controller 520 in accordance with this example embodiment. The memory 510 may be a non-volatile memory device manufactured by example embodiments. The memory controller 520 may provide an input signal for controlling an operation of the memory 510. For example, the memory controller 520 may provide an input signal of a DRAM device like a command (CMD) signal, an address (ADD) signal and an I/O signal. The memory controller 520 may control data of the DRAM device based on the input signal.

FIG. 26 is a block diagram illustrating another electronic device including a non-volatile memory device in accordance with example embodiments.

Referring to FIG. 26, the electronic device may include a memory 510 connected to a host system 700 in accordance with example embodiments. The memory 510 may be a non-volatile memory device manufactured in accordance with example embodiments. The host system 700 may include an electronic appliance like a personal computer, a camera, a mobile device, a game machine, a telecommunication device, etc. The host system 700 may apply an input signal for controlling and operating the memory 510. The memory 510 may be used as a data storing medium.

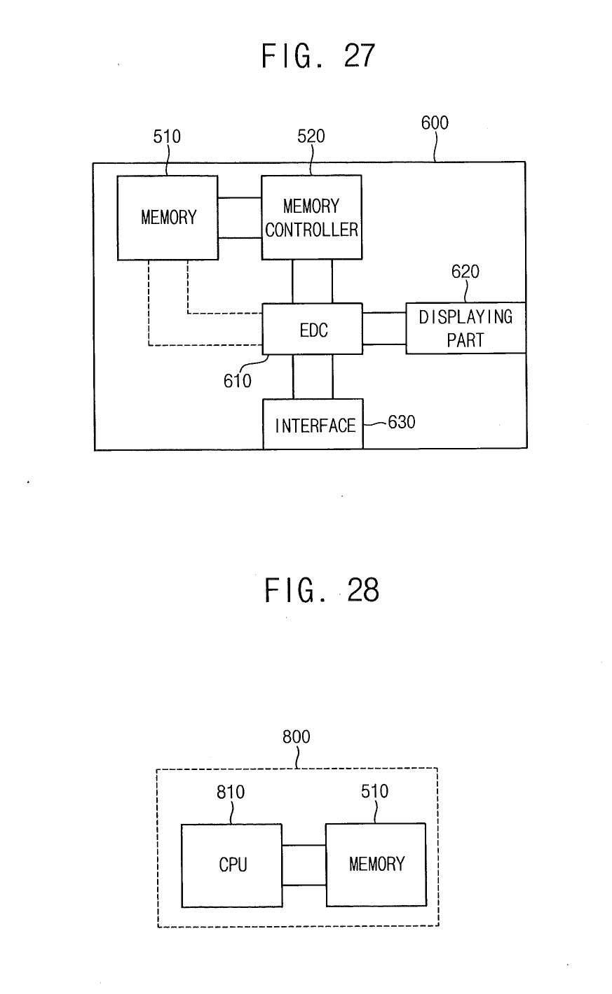

FIG. 27 is a block diagram illustrating further another electronic device including a non-volatile memory device in accordance with example embodiments.

Referring to FIG. 27, a portable apparatus 600 is illustrated in accordance with this example embodiment. The portable apparatus 600 may include an MP3 player, a video player, a complex device of a video and audio player, etc. The portable device 600 may include a memory 510 and a memory controller 520 as illustrated in FIG. 27. The portable device 600 may include an encoder/decoder 610, a displaying part 620 and an interface 630. Data of audio, video, etc., may be input/output from the memory 510 through the memory controller 520 by the encoder/decoder 610.

FIG. 28 is a block diagram illustrating still further another electronic device including a non-volatile memory device in accordance with example embodiments.

Referring to FIG. 28, a memory 510 may be connected to a central processing unit (CPU) 810 in a computer system 800. For example, the computer system 800 may be a personal computer, a personal data assistant, etc. The memory 510 may be connected to the CPU 810 directly or via a bus. The memory 510 may be a non-volatile memory device manufactured in accordance with example embodiments. Even though each element is not illustrated in detail in FIG. 28, the computer system 800 may include the elements.

As described above, a non-volatile memory device including a gate structure including a NiSi phase and having an improved thermal stability and a low resistance may be manufactured in accordance with example embodiments.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1-6. (canceled)

7. A method of manufacturing a non-volatile memory device, comprising:
forming a tunnel oxide layer, a preliminary charge storing layer and a dielectric layer on a semiconductor layer;
forming a first polysilicon layer on the dielectric layer;
forming a barrier layer on the first polysilicon layer;
forming a second polysilicon layer on the barrier layer, wherein the barrier layer is configured to block migration of silicon from the first polysilicon layer to the second polysilicon layer;
patterning the second polysilicon layer, the barrier layer, the first polysilicon layer, the dielectric layer, the preliminary charge storing layer and the tunnel oxide layer to form a tunnel layer pattern, a charge storing layer pattern, a dielectric layer pattern, a first control gate pattern, a barrier layer pattern and a second polysilicon pattern;
forming a nickel layer on the second polysilicon pattern; and
performing a heat treatment on the second polysilicon pattern and the nickel layer to form a second control gate pattern including NiSi on the barrier layer pattern.

8. The method of claim 7, wherein the barrier layer comprises tungsten (W), titanium (Ti), tantalum (Ta), cobalt titanium (CoTi), nickel platinum (NiPt), titanium nitride (TiN), tantalum nitride (TaN), cobalt silicide (CoSi2), tungsten silicide (WSix), molybdenum silicide (MoSix), platinum silicide (PtSix), titanium silicide (TiSix) and/or nickel cobalt silicide (NiCoSix), wherein x represents a real number.

9. The method of claim 8, wherein the barrier layer is formed by using tungsten silicide (WSix).

10. The method of claim 7, wherein the barrier layer has a thickness of from about 50 angstoms to about 150 angstoms.

11. The method of claim 7, wherein the second control gate pattern is formed at a temperature range of about 320° C. to about 750° C.

12. The method of claim 7, wherein the second control gate pattern is formed by:
performing a first heat treatment of the second polysilicon pattern and the nickel layer at a temperature range of about 320° C. to about 350° C.; and
performing a second heat treatment of the second polysilicon pattern and the nickel layer at a temperature range of about 400° C. to about 650° C.

13. The method of claim 7, further comprising a forming process of a blocking layer on a sidewall of the tunnel layer pattern, the charge storing layer pattern, the dielectric layer pattern, the first control gate pattern, the barrier layer pattern and the second polysilicon pattern.

14. The method of claim 7, wherein the charge storing layer pattern includes polysilicon provided as a floating gate pattern.

15. The method of claim 7, wherein the charge storing layer pattern includes silicon nitride or a metal oxide provided as a charge trapping layer pattern.

16. The method of claim 7, further comprising forming a capping layer on the nickel layer.

17. The method of claim 7, further comprising removing remaining portions of the nickel layer after forming the second control gate pattern.

18. The method of claim 7, further comprising performing a process on the non-volatile memory device a temperature of about 650° C. or higher after forming the second control gate pattern.
